(19) United States
(12) Patent Application Publication
(10) Pub. No.: US 2024/0394178 A1
(43) Pub. Date: Nov. 28, 2024

(54) STACKED MEMORY DEVICE WITH INTERFACE DIE

(71) Applicant: Rambus Inc., San Jose, CA (US)

(72) Inventor: Torsten Partsch, San Jose, CA (US)

(21) Appl. No.: 18/701,574

(22) PCT Filed: Oct. 20, 2022
(86) PCT No.: PCT/US22/78416

§ 371 Date: Apr. 15, 2024

Related U.S. Application Data
(60) Provisional application No. 63/272,143, filed on Oct. 26, 2021.

(51) Int. Cl. G06F 12/02; G06F 13/16; G11C 7/10

(52) U.S. Cl. CPC G06F 12/0223; G06F 13/1668; G11C 7/10; G06F 2213/16

(57) ABSTRACT

A stacked memory device comprises a stack of dies including respective core memories. An interface die in the stack includes interface circuitry for interfacing between a data bus coupled to a memory controller and the respective core memories of the stack of dies. The interface circuitry may implement decoding of data received from the data bus for the respective core memories and encoding of data sent to the data bus from the respective core memories. The respective core memories of the stacked memory device may be arranged in two or more ranks. A memory module includes a set of stacked memory devices. The stacked memory devices may be arranged in various configurations having varying numbers of channels, ranks, and data widths.

### BACKGROUND

Memory systems typically include a memory controller and a memory module having one or more memory devices. The memory controller sends commands to the memory module to facilitate writing data to the memory devices and reading data from the memory devices.

### BRIEF DESCRIPTION OF THE DRAWINGS

The teachings of the embodiments herein can be readily understood by considering the following detailed description in conjunction with the accompanying drawings.

FIG. 1 is a block diagram of a stacked memory device.

FIG. 2 is diagram illustrating a physical structure of a stacked memory device.

FIG. 3 is a first example embodiment of a memory module using stacked memory devices.

FIG. 4 is a second example embodiment of a memory module using stacked memory devices.

FIG. 5 is a third example embodiment of a memory module using stacked memory devices.

FIG. 6 is a fourth example embodiment of a memory module using stacked memory devices.

FIG. 7 is a fifth example embodiment of a memory module using stacked memory devices.

FIG. 8 is a sixth example embodiment of a memory module using stacked memory devices.

FIG. 9 is a flowchart illustrating an example embodiment of a process for writing to a stacked memory device.

FIG. 10 is a flowchart illustrating an example embodiment of a process for reading from a stacked memory device.

### DETAILED DESCRIPTION

A stacked memory device comprises a stack of dies including respective core memories. An interface die in the stack includes interface circuitry for interfacing between a data bus coupled to a memory controller and the respective core memories of the stack of dies. The interface circuitry may implement decoding of data received from the data bus for the respective core memories and encoding of data sent to the data bus from the respective core memories. The respective core memories of the stacked memory device may be arranged in two or more ranks. A memory module includes a set of stacked memory devices. The stacked memory devices may be arranged in various configurations having varying numbers of channels, ranks, and data widths.

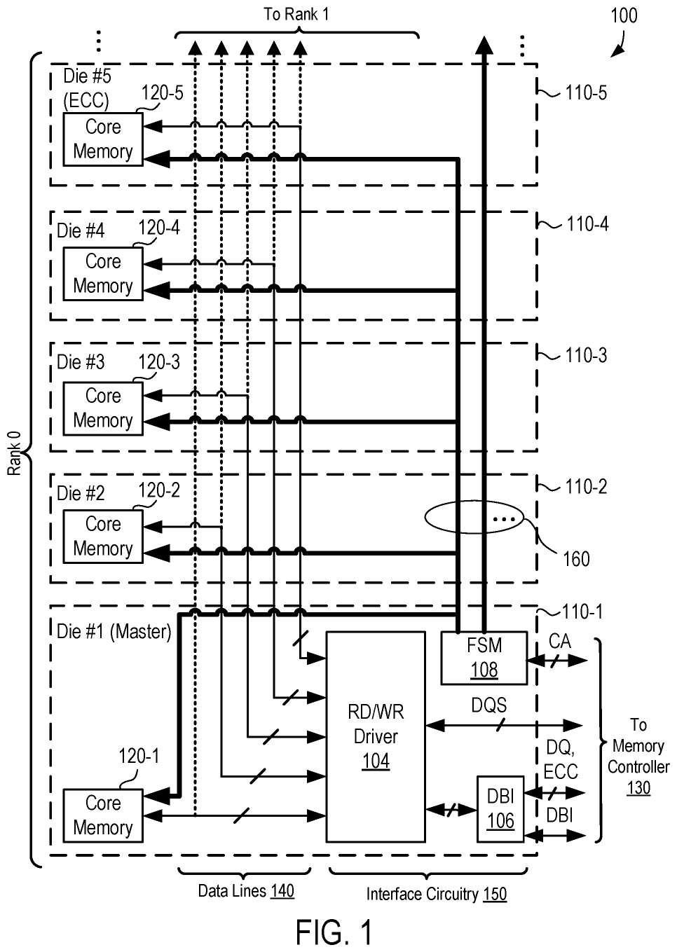

FIG. 1 illustrates an example embodiment of a stacked memory device 100. The stacked memory device 100 comprises a plurality of dies 110 arranged in a stack (e.g., dies 110-1, 110-2, etc.). The stacked memory device 100 may be embodied as a three-dimensional physical structure in which the primary surfaces of each die 110 are arranged in substantially parallel x-y planes that each intersect different points along a z-axis. Thus, the dies 110 may be vertically stacked when the primary surfaces of the dies 110 are parallel to a horizontal plane. Electronic connections between different dies 110 in the stack may be made using through-silicon via (TSV) technology or other interconnection technology.

Each of the dies 110 in the stack includes a core memory 120. One of the dies 110 in the stack comprises a master die 110-1 that also includes interface circuitry 150 such as a read/write (RD/WR) driver 104, data bus inversion (DBI) logic 106, a finite state machine (FSM) 108, and associated connections for interfacing between the core memories 120 and a data bus coupled to a memory controller 130. In the illustrated embodiment, the bottom-most die 110-1 in the stack operates as the master die 110-1. Alternatively, a different die 110 in the stack may operate as the master die 110-1. Data lines 140 couple between the interface circuitry 150 and each of the core memories 120.

The stacked memory device 100 may include multiple ranks of core memories 120. Here, a rank comprises a set of core memories 120 externally selected by the same commands, using either one-hot chip select (CS) signals or an encoded CS bus accompanying the external commands. Internal control and address lines 160 are shared by the core memories 120 of the same rank, such that the set of core memories 120 in the same rank are accessed concurrently and operate responsive to the same commands (e.g., read, write, activate, or precharge). The internal control and address lines 160 are generated by the FSM 108 in the master die 110-1 based on the addresses and commands CA externally provided by the memory controller 130. In contrast, core memories 120 in different ranks are responsive to different CS signals (or CS bus values) and share different internal control and address lines 160 and thus do not operate in response to the same commands as the other rank(s). Core memories 120 in different ranks may share the same data lines 140. Thus, each rank may comprise a set of core memories 120 connected in parallel to respective data lines 140. While FIG. 1 only explicitly illustrates connections to a second rank, the stacked memory device 100 may include any number of additional ranks coupled in parallel to the data lines 140. The core memories 120 of the additional rank(s) may be embodied in respective additional dies 110 in the stack. For example, rank 1 may comprise an additional set of five dies 110 (with respective core memories 120) stacked on top of the illustrated set of five dies 110 of rank 0. The additional ranks may share the same interface circuitry 150 of the master die 110-1. In other words, a memory device 100 with multiple ranks may have only a single master die 110-1 with interface circuitry 150 shared between the ranks.

In a write operation, bits of an input (x-bit wide-) word received from the memory controller 130 over the external data bus are spread across the different core memories 120 in a rank. Similarly, in a read operation, different bits are read from different core memories 120 in a rank, aggregated into an output word, and outputted to the memory controller 130 via the data bus. Here, a word may include both a data payload (DQ) portion and an error correction code (ECC) portion. In an example embodiment, the stacked memory device 100 connects (via pins) to eight DQ lines (D0-D7) and two ECC lines (ECC0-ECC1) to communicate 10-bit wide words to or from the memory controller 130 via the data bus.

The core memories 120 may be configured for burst communications. Here, multiple words may be written to or read from a rank of core memories 120 in parallel. For example, for a burst length of four, four 10-bit signals received via the DQ and ECC lines during a write operation may be parallelized and written to the rank of core memories 120 concurrently. Similarly, during a read operation, four 10-bit signals may be read from the rank of core memories in parallel and serially outputted via the DQ and ECC lines as 10-bit wide signals.

The width of the data lines connected to each core memory 120 (for data or ECC bits respectively) may be given by the product of the burst length (BL) and the number DQ pins associated with the core memory 120. In one example, four of the core memories 120-1, 120-2, 120-3, 120-4 operate as DQ memories that are each allocated to two of the DQ pins. Thus, in this example, the width of the data lines connected to each core memory is 2*4=8. For example, when reading or writing 8-bit wide DQ data (via D0-D7 pins), the core memory 120-1 performs operations associated with pins D0-D1, the core memory 120-2 performs operations associated with pins D2-D3, the core memory 120-3 performs operations associated with pins D4-D5, and the core memory 120-4 performs operations associated with pins D6-D7. A fifth core memory 120-5 operates as a dedicated ECC memory allocated to the two ECC pins (ECC0-ECC1). Similar allocations of pins to core memories 120 may be similarly configured for additional ranks.

The interface circuitry 150 comprises an RD/WR driver 104 and DBI logic 106. The DBI logic 106 interfaces with a data bus to communicate encoded data signals with the memory controller 130. For write commands, the DBI logic 106 receives the encoded signals, decodes the signals, and outputs the decoded signals to the RD/WR driver 104. For read commands, the DBI logic 106 receives unencoded signals from the RD/WR driver 104, encodes the signals, and outputs the encoded signals to the memory controller 130.

In DBI encoding/decoding, the encoded data signals include data payloads (DQ), error correction codes (ECC), and a DBI signal. A polarity of the DBI signal indicates an inversion state of the DQ and ECC bits. For example, a first polarity of the DBI signal indicates that the DQ and ECC bits are inverted in the encoded signal and a second polarity of the DBI signal indicates that the DQ and ECC bits are not inverted in the encoded signal. To perform decoding (e.g., during a write operation), the DBI logic 104 receives an encoded word (per DQS edge) (e.g., eight DQ bits, two ECC bits, and one DBI bit), detects a polarity of the DBI bit and selectively inverts the DQ and ECC bits depending on the polarity of the DBI bit. To perform encoding (e.g., during a read operation), the DBI logic 106 receives an unencoded word (e.g., eight DQ bits and two ECC bits), determines whether or not to invert the word, and generates a DBI bit with a polarity that indicates whether or not the word is inverted. Here, the decision of whether or not to invert the word may be based on whether the number of low bits (or, alternatively, high bits) in the word exceeds a threshold number.

In alternative embodiments, a different encoding/decoding logic may be used in place of the DBI logic 106. Alternatively, the data can be encoded per pin during a burst access to reduce inter symbol interference ISI (instead across all pins per edge.) In this scenario, the encoding conditionally inverts the data burst on a DQ line, as opposed to each word, transmitted or received per DQS edge to reduce power noise and crosstalk.

The RD/WR driver 104 interfaces between the DBI logic 106 and the core memories 102 via the set of data lines 140. The RD/WR driver 104 may also communicate other external signals with the memory controller 130 (such as DQS). During write operations, the RD/WR driver 104 receives the decoded data signal (including ECC data) from the DBI logic 106 and transmits the decoded data to the respective core memories 120 on their respective data lines 140. For example, the RD/WR driver 104 receives an input word containing eight bits of data and two bits of ECC for writing to rank 0, transmits bits D0, D1 to the core memory 120-1 of the first die 110-1, transmits bits D2, D3 to the core memory 120-2 of the second die 110-2, transmits bits D4, D5 to the core memory 120-3 of the third die 110-3, transmits bits D6, D7 to the core memory 120-4 of the fourth die 110-4, and transmits the ECC bits ECC0, ECC1 to the core memory 120-5 of the fifth (ECC) die 110-5. In a read command, the RD/WR driver 104 receives respective bits from each of the core memories 102 via their respective data lines 140 and transmits the word to the DBI logic 106. For example, to implement a read from rank 0, the RD/WR driver 104 receives bits D0, D1 from the core memory 120-1 of the first die 110-1, receives bits D2, D3 from the core memory 120-2 of the second die 110-2, receives bits D4, D5 from the core memory 120-3 of the third die 110-3, receives bits D6, D7 from the core memory 120-4 of the fourth die 110-4, and receives the ECC bits ECC0, ECC1 from the core memory 120-5 of the fifth (ECC) die 110-5. The RD/WR driver 104 aggregates the bits and transmits the word including the DQ bits D0-D7 and ECC bits ECC0-ECC1 to the DBI logic 106 for encoding.

The RD/WR driver 104 may be configured for burst communications in which the RD/WR driver 104 parallelizes a set of words received from the DBI logic 104 before transmitting them to the core memories 120 and vice versa. In this case, the number of interface data lines 140 between each core memories 120 and the RD/WR driver 104 may comprise a product of the burst length (BL) and the number of associated DQ pins per core memory 120. For example, if each core memory 120 is associated with two DQ pins and the burst length is four, there are 2*4=8 interface lines 140 to each core memory 120. In a write operation, the RD/WR driver 104 receives four words of input data and transmits the four words in parallel to the core memories 120. Each core memory thus receives eight bits of data per write operation (two bits per word per core memory 120). In a read operation, the RD/WR driver 104 similarly receives eight bits of data in parallel from each core memory 120 over the respective interface data lines 140 (two bits per word per core memory 120), which are assembled into four output words for transmitting to the DBI logic 104.

The memory device 100 may include additional circuits and data, address and control lines that are omitted from FIG. 1. For example, the memory device 100 includes circuits and interfaces for communicating command, address, and other control information with the core memories 120 and/or external components.

In an alternative embodiment, the order of the DBI logic 106 and the RD/WR driver 104 may be reversed. For example, in a read operation, the interface circuitry 150 could first encode the data read from the core memories 120 and then aggregate them for outputting the DQ and ECC pins.

The memory device 100 may have any number of ranks. For example, the memory device 100 may comprise a single rank (e.g., five dies), two ranks (e.g., 10 dies), four ranks (e.g., 20 dies), eight ranks (e.g., 40 dies), or any other number of ranks. In alternative embodiments, the ECC die 110-5 may be omitted and each rank may comprise only four dies instead of five. In other alternative embodiments, additional ECC dies 110-5 may be included to enable stronger error detection/correction and each rank may include six or more dies 110. In yet further alternative embodiments, the memory device 100 may include memory cores 120 having other widths (e.g., 16, 32, 64, etc.) or the memory device 100 may have a different overall width (e.g., ×4, ×8, ×16, etc.). In each of these variations, an appropriate number of dies 110 in each rank may be present to accommodate the memory widths.

In an alternative embodiment, the core memory 120-1 of the master die 110-1 may be omitted or disabled. In this example, the master die 110-1 operates as a dedicated interface die without an integrated core memory 120-1. In other embodiments, all of the dies 110 may be manufactured identically and include all components of the master die 110-1. Here, the dies 110 may be individually configurable to operate as either a master die 110-1 (by enabling functionality of the interface circuitry 150) or as a standard (non-master) die (e.g., dies 110-2, 110-3, 110-4, 110-5) by decoupling or disabling the functionality of the interface circuitry 150.

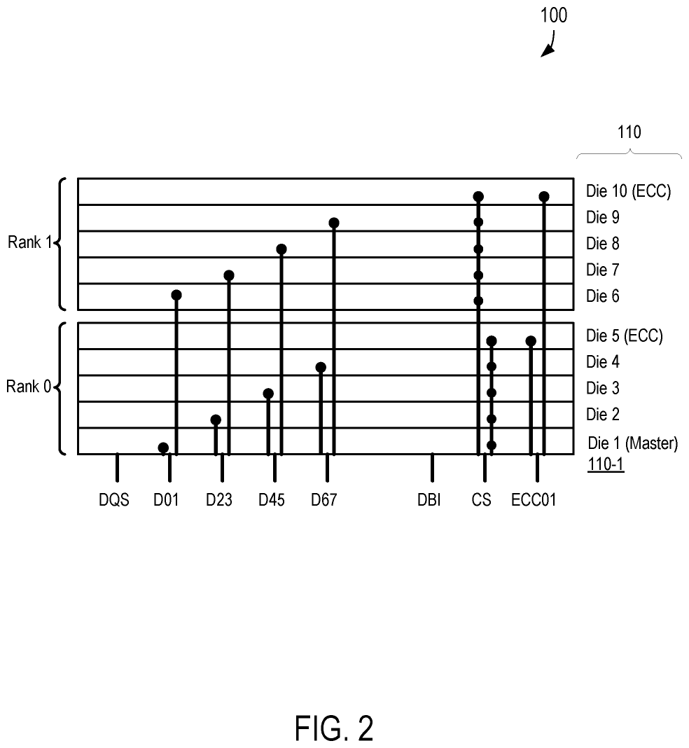

FIG. 2 illustrates another view of the stacked memory device 100. In this view, two ranks are shown embodied in a stack of ten dies 110 (five dies 110 per rank). Each die 110 is associated with two DQ pins and is therefore coupled to two external lines of the stacked memory device 100. For example, dies 1 and 6 are coupled to communicate data bits D0, D1; dies 2 and 7 are coupled to communicate data bits D2, D3; dies 3 and 7 are coupled to communicate data bits D4-D5; dies 4 and 8 are coupled to communicate data bits D6-D7; and dies 5 and 10 are coupled to communicate ECC bits ECC0-ECC1. FIG. 2 also illustrates two internal select lines that selectively access one of the ranks based on the externally supplied chip select (CS) signal. A first select line is coupled to each of the dies 110 in rank 0 and a second select line is coupled to each of the dies 110 in rank 1. DQS and DBI are illustrated as being coupled only to the master die 110-1 because these signals interact only with the interface circuitry 150 of the master die 110-1.

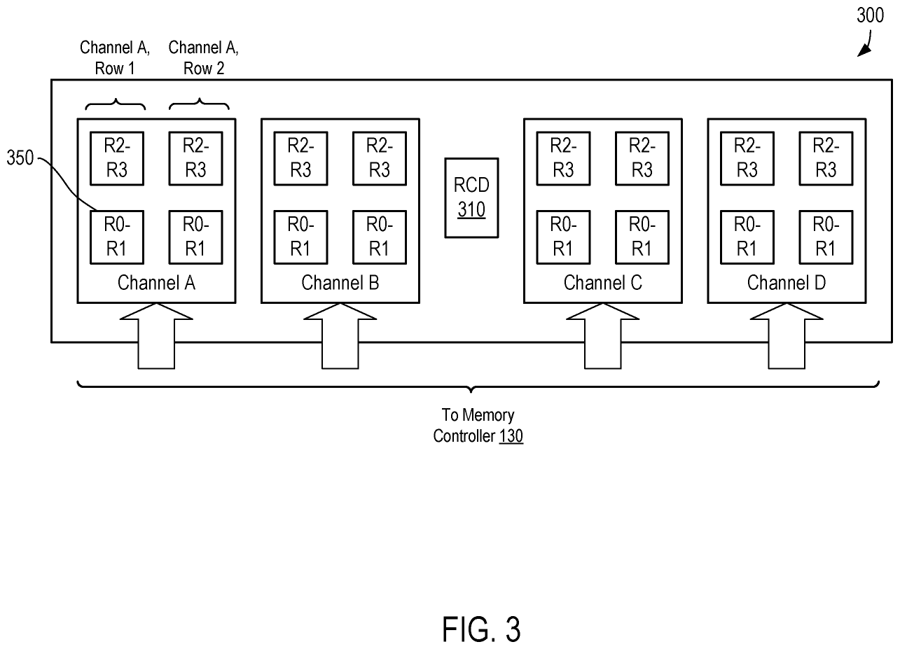

FIG. 3 illustrates an example embodiment of a memory module 300. The memory module 300 includes a register clock driver (RCD) 310 and a plurality of stacked memory devices 350 organized into channels. The RCD 310 communicates command/address, clock, or other control signals (not shown) between the memory controller 130 and the set of memory devices 350. The memory module 300 comprises four ranks (e.g., rank R0-R3) and four channels (e.g., channels A-D). Each channel includes two rows of two memory devices 350 each. The rows operate in parallel such that the width of the channel is determined by the width of each memory device 350 and number of rows. Within each row, a first memory device 350 corresponds to ranks R0-R1 and a second memory device 350 corresponds to ranks R2-R3. Thus, ranks are spread across multiple physical memory devices 350 and memory cores 120 in the same rank may reside in different physical memory devices 350 within a channel.

In one example architecture, each channel includes 16 data (DQ) lines (eight per row), four DQS/DQSb lines (operating as one differential data strobe per row), four ECC lines (two per row) and two DBI lines (one per row) for a total of 26 lines (13 per row) per channel (not including command/address or other signals).

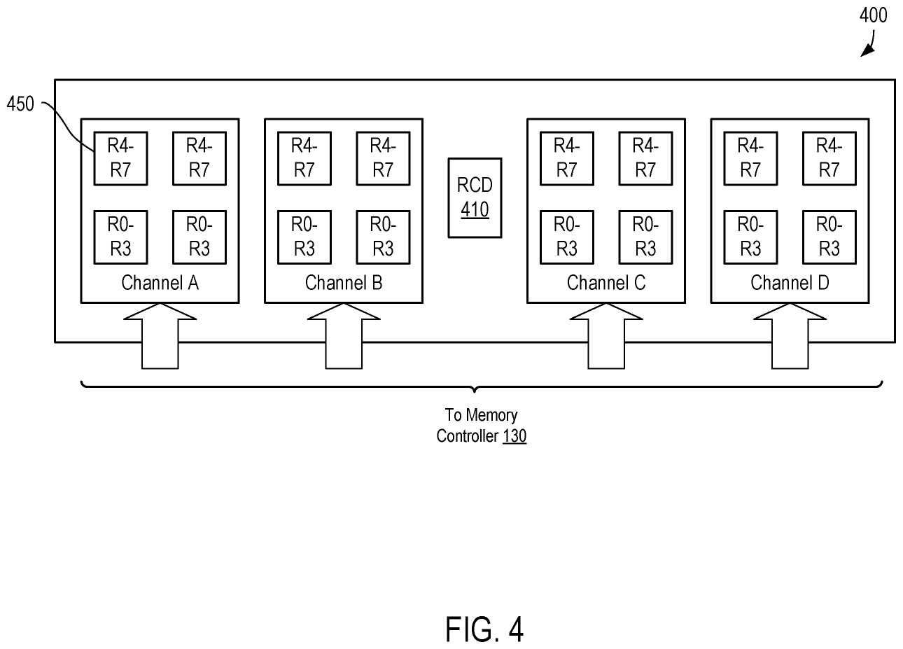

FIG. 4 illustrates another example embodiment of a memory module 400. The memory module 400 comprises an RCD 410 and a set of stacked memory devices 450 organized into eight ranks (e.g., ranks R0-R7) and four channels (e.g., channels A-D). The stacked memory devices 450 are similar to those depicted in FIGS. 1-2 except that they each comprise four ranks embodied as a stack of 20 dies. Each channel includes two rows of two memory devices 450 in which two stacked memory devices 450 correspond to ranks R0-R3 and two stacked memory devices 450) correspond to ranks R4-R7. The memory module 400 may have generally the same external pin configuration as the memory module 300 described above.

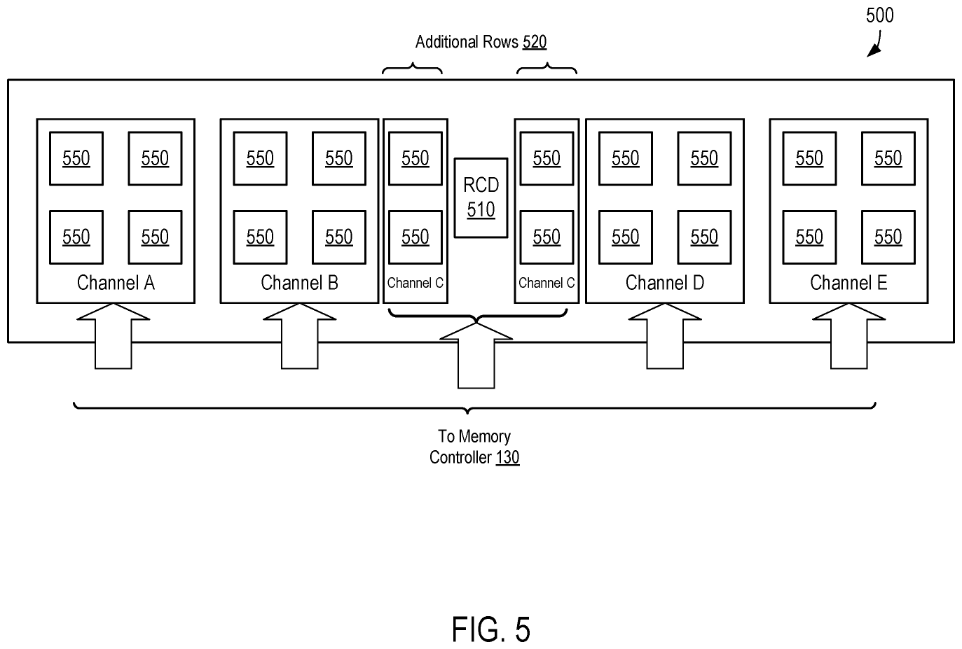

FIG. 5 illustrates another example embodiment of a memory module 500. The memory module 500 includes an RCD 510 and five channels that each comprise two rows of two memory devices 550. Thus, the memory module 500 includes two additional rows 520 relative to the memory modules 300, 400 of FIGS. 3-4. The memory devices 550 may comprise any number of ranks (e.g., 2-rank devices, 4-rank devices, 8-rank devices, etc.)

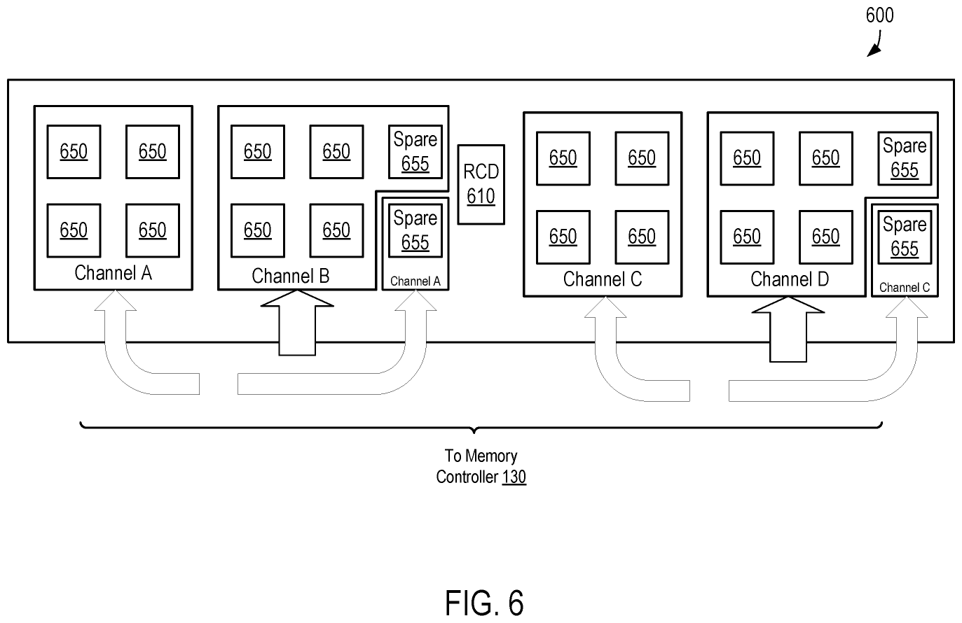

FIG. 6 illustrates another example embodiment of a memory module 600. The memory module 600 comprises an RCD 610 and four channels each comprising five stacked memory devices 650. This memory module 600 may be similar to the memory modules 300, 400 of FIGS. 3-4 but includes a spare memory device 655 in each channel. The spare memory device 655 in each channel can be used for various purposes. For example, in one embodiment, the spare memory device 655 can be used to store additional ECC bits (e.g., to enable up to 16-bit wide error correction per channel), channel metadata, or a combination thereof. In another embodiment, the spare memory device 655 may operate as a replacement memory device in the event that uncorrectable errors are detected in a primary memory device 650. In another embodiment, the spare memory device 655 may be used to increase the data width of the channel (e.g., to 24 bits of DQ and six bits of ECC).

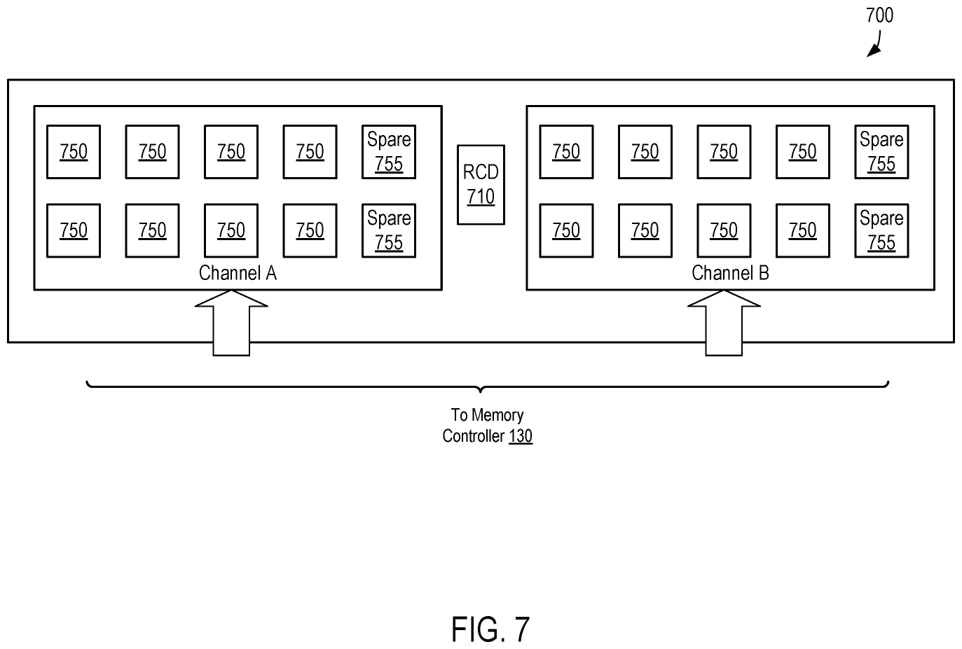

FIG. 7 illustrates another example embodiment of a memory module 700. In this example, the memory module 700 comprises an RCD 710 and two channels (A, B) that each have five rows of stacked memory devices 750, 755. Within each channel, four rows operate as primary memory devices 750) and one row operates as spare memory devices 755. The spare memory devices 755 may operate as backup devices in the event of a failure of a primary memory device 750) or may store extra data (e.g., extra ECC data or channel metadata) as described above.

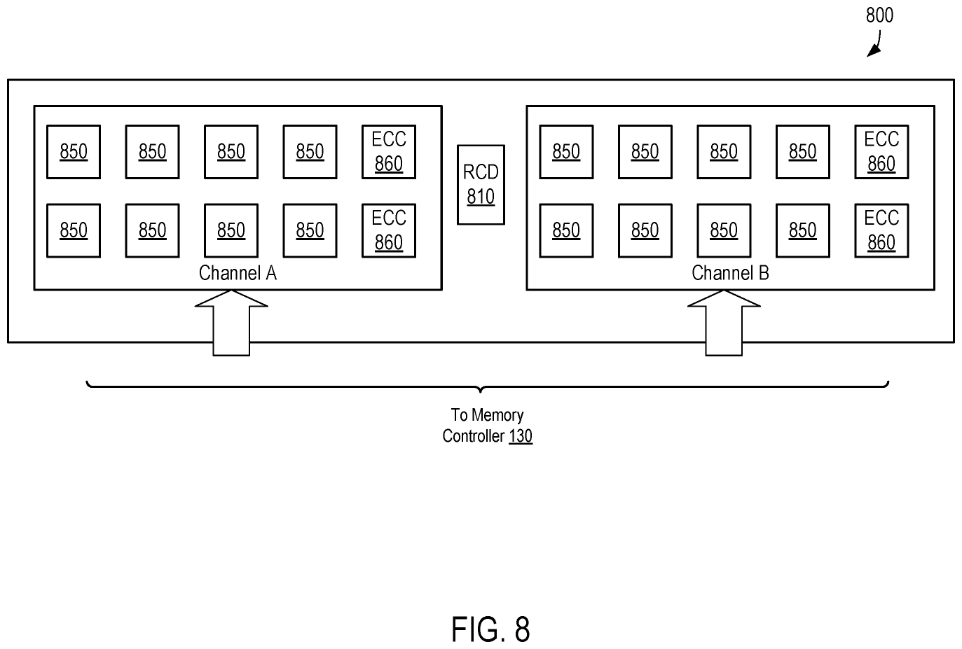

FIG. 8 illustrates another example embodiment of a memory module 800. In this example, the memory module 800 comprises an RCD 810 and two channels of five rows each with two stacked memory devices 850, 860 per channel. Unlike the memory devices 100 of FIGS. 1-2 described above, the stacked memory devices 850 do not necessarily include an ECC die (e.g., each memory device 850 includes four dies per rank instead of five). Instead, the memory module 800 includes dedicated ECC devices 860 (e.g., two per channel) that store the ECC bits. For example, each channel of the memory module 800 may comprise 32 DQ lines (eight per row of primary memory devices 850) and eight ECC lines coupled to the row of ECC memory devices 860. The ECC memory devices 860 and the primary memory devices 850 may be identical in structure.

In an embodiment, any of the example memory modules 300-800 of FIGS. 3-8 may include data buffer chips in each row to redrive the data signal to and from the memory devices (LRDIMM). Alternatively, the memory modules 300-800 may optionally omit the RCDs 310-810.

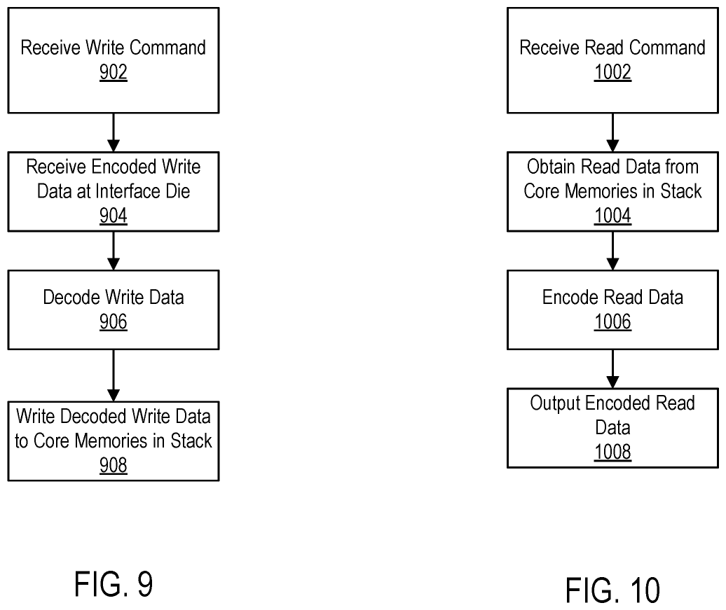

FIG. 9 is a flowchart illustrating an example embodiment of a process for writing to a stacked memory device. The stacked memory device receives 902 a write command and receives 904 encoded write data from a data bus at the interface die. The interface circuitry of the interface die decodes 906 the write data and writes 908 the decoded write to the set of core memories (located on separate dies) in the appropriate rank of the stacked memory device.

FIG. 10 is a flowchart illustrating an example embodiment of a process for reading from a stacked memory device. The stacked memory device receives 1002 a read command. The interface circuitry of the interface die obtains read data from a set of core memories (located on separate dies) in the appropriate rank of the stacked memory device 1004. The interface circuitry aggregates and encodes 1006 the read data and outputs 1008 the encoded read data to the data bus.

The foregoing description has been presented in terms of core memory (e.g., core memory 120) that are dynamic (i.e., DRAM arrays). However, the core memories 120 may alternatively include one or more other types of core memory such as static random access memory (SRAM), non-volatile core memory (such as flash), conductive bridging random core memory (CBRAM—a.k.a., programmable metallization cell—PMC), resistive random core memory (a.k.a., RRAM or ReRAM), or magneto-resistive random-access memory (MRAM), and the like. These embodiments may operate according to the same principles described herein.

Upon reading this disclosure, those of ordinary skill in the art will appreciate still alternative structural and functional designs and processes for the described embodiments, through the disclosed principles of the present disclosure. Thus, while embodiments and applications of the present disclosure have been illustrated and described, it is to be understood that the disclosure is not limited to the precise construction and components disclosed herein. Various modifications, changes and variations which will be apparent to those skilled in the art may be made in the arrangement, operation and details of the method and apparatus of the present disclosure herein without departing from the scope of the disclosure as defined in the appended claims.

1. A stacked memory device comprising:
a set of dies arranged in a stack and comprising respective core memories; and
an interface die in the stack, the interface die including:
encoding/decoding logic to decode write data received from a data bus and to encode read data for outputting to the data bus; and
read/write driver logic to receive the decoded write data from the encoding/decoding logic and to distribute the decoded write data to the respective core memories, and to receive the read data from the respective core memories for providing to the encoding/decoding logic.

2. The stacked memory device of claim 1, wherein the interface die includes an integrated core memory, wherein the read/write driver logic further communicates a portion of the decoded write data to the integrated core memory, and wherein the read/write driver logic further receives a portion of the read data from the integrated core memory.

3. The stacked memory device of claim 1, wherein the encoding/decoding logic decodes the write data and encodes the read data according to a data bus inversion encoding/decoding scheme.

4. The stacked memory device of claim 1, wherein the respective core memories are configured to operate as at least two different ranks having different chip selects.

5. The stacked memory device of claim 1, wherein at least one of the respective core memories is configured to store a payload portion of the decoded write data and wherein at least one of the respective core memories comprises a dedicated error correction code memory configured to store error correction code data of the decoded write data.

6. The stacked memory device of claim 1, wherein a data width of the memory device is not a power of 2.

7. The stacked memory device of claim 1, wherein the respective core memories of the set of dies are connected to the read/write driver logic by data lines including through silicon vias.

8. A memory module comprising:
a data bus interface for coupling to a memory controller via a data bus; and
a set of stacked memory devices coupled to the data bus interface, wherein each of the set of stacked memory devices comprises:
a set of dies arranged in a stack and comprising respective core memories;
an interface die in the stack, the interface die including:
encoding/decoding logic to decode write data received from the data bus and to encode read data for outputting to the data bus; and
read/write driver logic to receive the decoded write data from the encoding/decoding logic and to distribute the decoded write data to the respective core memories, and to receive the read data from the respective core memories for providing to the encoding/decoding logic.

9. The memory module of claim 8, wherein the set of stacked memory devices are organized into a plurality of channels, each of the plurality of channels comprising at least two rows of stacked memory devices, and each of the at least two rows comprising two stacked memory devices operating in different ranks.

10. The memory module of claim 8, wherein each of the stacked memory devices comprises two ranks.

11. The memory module of claim 8, wherein each of the stacked memory devices comprises four ranks.

12. The memory module of claim 8, wherein the set of stacked memory devices are organized into four channels each having four stacked memory devices.

13. The memory module of claim 8, wherein the set of stacked memory devices are organized into five channels each having four stacked memory devices.

14. The memory module of claim 8, wherein the set of stacked memory devices are organized into four channels each having five stacked memory devices.

15. The memory module of claim 8, wherein the set of stacked memory devices are organized into a plurality of channels, wherein within each channel, a first subset of the stacked memory devices operate as primary memory devices and at least one of the stacked memory devices operate as an extra memory device for storing channel metadata associated with data stored to the primary memory devices.

16. The memory module of claim 8, wherein the set of stacked memory devices are organized into a plurality of channels, wherein within each channel, a first subset of the stacked memory devices operate as primary memory devices and at least one of the stacked memory devices operates as a spare stacked memory device that is enabled in an event of a failure of one of the primary memory devices.

17. The memory module of claim 8, wherein the set of stacked memory devices are organized into a plurality of channels, wherein within each channel, a first subset of the stacked memory devices operate as standard memory devices and a second subset of the stacked memory devices operate as dedicated ECC memory devices for storing ECC bits associated with data stored to the standard memory devices.

18. A method for operating a stacked memory device, the method comprising:
receiving, at an interface die of the stacked memory device from a data bus, a write command and encoded write data for writing to the memory device;
decoding, by encoding/decoding logic of the interface die, the encoded write data to generate decoded write data;
writing, by read/write logic of the interface die, different subsets of bits of the decoded write data to different core memories in different dies of the stacked memory arranged in a stack;
receiving, at the interface die of the stacked memory device, a read command for reading from the stacked memory device;
obtaining different subsets of bits of read data from the different core memories in the different dies of the stacked memory device responsive to the read command;
aggregating, by the read/write logic of the interface die, the different subset of bits of the read data to generate aggregated read data;
encoding, by the encoding/decoding logic of the interface die, the aggregated read data into encoded read data; and
outputting, by the encoding/decoding logic, the encoded read data to the data bus.

19. The method of claim 18, wherein the decoding the encoded write data comprises applying a data bus inversion decoding and where encoding the aggregated read data comprises applying a data bus inversion encoding.

20. The method of claim 18, wherein writing the decoded write data comprises selecting a rank associated with the write command from a plurality of ranks of the stacked memory device, and writing the different subsets of bits of the decoded write data to core memories in the selected rank.
